(19) United States
(12) Patent Application Publication
(10) Pub. No.: US 2023/0329051 A1
(43) Pub. Date: Oct. 12, 2023

(54) DISPLAY DEVICE

(71) Applicant: Samsung Display Co., Ltd., Yongin-si (KR)

(72) Inventors: KEONWOO KIM, Yongin-si (KR); DEOK-YOUNG CHOI, Yongin-si (KR); DEUKJONG KIM, Yongin-si (KR)

(21) Appl. No.: 18/188,303

(22) Filed: Mar. 22, 2023

(30) Foreign Application Priority Data
Apr. 6, 2022 (KR) 10-2022-0042874

(51) Int. Cl. H10K 59/131; G09G 3/20; G09G 3/3208; H10K 59/121; H10K 59/126

(52) U.S. Cl. CPC H10K 59/131; G09G 3/2096; H10K 59/126; H10K 59/1213; G09G 3/3208

(57) ABSTRACT

A display device includes a display panel, an electronic component including a silicon transistor having a first gate and an oxide transistor having a second gate, and a conductive adhesive layer, wherein the display panel includes a base layer, a pixel, a signal line having an end portion on a same layer as the second gate, a signal pad, a lower insulation layer, and an upper insulation layer having a contact hole defined thereon, wherein the end portion is on the lower insulation layer, and includes a first portion exposed by the contact hole and a second portion covered by the upper insulation layer, and the signal pads includes an uppermost conductive pattern electrically connected to the end portion of the signal line, wherein the electronic component includes a connection terminal on the uppermost conductive pattern.

### CROSS-REFERENCE TO RELATED APPLICATIONS

The present application claims to and the benefit of Korean Patent Application No. 10-2022-0042874, filed on Apr. 6, 2022, in the Korean Intellectual Property Office, the entire contents of which are hereby incorporated by reference.

### BACKGROUND

### 1. Field

Aspects of some embodiments of the present disclosure herein relate to a display device.

### 2. Description of Related Art

Various display devices used for multimedia devices such as a television, a mobile phone, a tablet computer, a navigation system, a game console are being developed. The display devices include a keyboard, a mouse, or the like as an input device. Also, the display devices are provided with an input sensor such as a touch panel as an input device.

A display device includes a display panel and a circuit board. The display panel may be connected to a main board through the circuit board. A driving chip may be mounted on the display panel.

The above information disclosed in this Background section is only for enhancement of understanding of the background and therefore the information discussed in this Background section does not necessarily constitute prior art.

### SUMMARY

Aspects of some embodiments of the present disclosure herein relate to a display device, and for example, to a pad region of a display device.

Aspects of some embodiments of the present disclosure include a display device in which signal pads have relatively reduced defects.

According to some embodiments of the inventive concept, a display device includes a display panel including a display region and a non-display region adjacent to the display region, an electronic component electrically connected to the display panel, and a conductive adhesive layer including an adhesive layer and a plurality of conductive balls in the adhesive layer and defining a single layer, and electrically connecting the display panel and the electronic component, wherein the display panel includes a base layer, a pixel on the base layer, and including a pixel driving circuit which includes a silicon transistor having a first gate, an oxide transistor having a second gate above the silicon transistor, and a shielding electrode between the first gate and the second gate and overlapping the oxide transistor, and a light emission element which is electrically connected to the pixel driving circuit, a signal line overlapping the non-display region, including an end portion on a same layer as the second gate, and electrically connected to the pixel driving circuit, a signal pad electrically connected to the end portion, a lower insulation layer on the base layer, and covering the silicon transistor, and an upper insulation layer on the lower insulation layer, covering the second gate, and having a contact hole defined thereon, wherein the end portion is on the lower insulation layer, and includes a first portion and exposed by the contact hole and a second portion covered by the upper insulation layer, and the signal pad includes an uppermost conductive pattern is on the end portion, and electrically connected to the end portion of the signal line, wherein the electronic component includes a connection terminal is on the uppermost conductive pattern, and electrically connected to the uppermost conductive pattern through the conductive adhesive layer.

According to some embodiments, the conductive balls may include a first conductive ball overlapping the first portion and the connection terminal, a second conductive ball overlapping the second portion and the connection terminal, and a third conductive ball not overlapping the connection terminal, wherein a separation distance between a portion overlapping the first portion of the uppermost conductive pattern in a thickness direction of the display panel and the electronic component and the connection terminal may be the same as or less than a diameter of the third conductive ball.

According to some embodiments, the separation distance between the portion overlapping the first portion of the uppermost conductive pattern in the thickness direction of the display panel and the electronic component and the connection terminal may be 3 μm or less.

According to some embodiments, the electronic component may be a driving chip, and the connection terminal may be a bump.

According to some embodiments, the uppermost conductive pattern may include a third portion corresponding to the first portion and a fourth portion corresponding to the second portion, wherein a height difference between the third portion and the fourth portion in the thickness direction of the display panel may be 1 μm or less.

According to some embodiments, the signal pad may further include an intermediate conductive pattern between the uppermost conductive pattern and the end portion, and electrically connecting the uppermost conductive pattern and the end portion.

According to some embodiments, the intermediate conductive pattern may include a first intermediate conductive pattern adjacent to the end portion, and a second intermediate conductive pattern between the first intermediate conductive pattern and the uppermost conductive pattern.

According to some embodiments, the upper insulation layer may have a sub-contact hole in a portion overlapping the second portion, wherein the second intermediate conductive pattern may be connected to the end portion through the sub-contact hole.

According to some embodiments, the display device may further include a first organic layer on the upper insulation layer, a second organic layer on the first organic layer, a first connection electrode between the upper insulation layer and the first organic layer, and electrically connected to the silicon transistor or the oxide transistor, and a second connection electrode between the first organic layer and the second organic layer, and connecting the first connection electrode and the light emission element.

According to some embodiments, the first intermediate conductive pattern and the first connection electrode may include the same material, and the second intermediate conductive pattern and the second connection electrode may include the same material.

According to some embodiments, the display device may further include an input sensor including at least one insulation layer and at least one conductive pattern layer, and on the display panel, wherein the uppermost conductive pattern and the at least one conductive pattern layer may include the same material.

According to some embodiments of the inventive concept, a display device includes a display panel including a display region and a non-display region adjacent to the display region, an electronic component electrically connected to the display panel, and a conductive adhesive layer including an adhesive layer and a plurality of conductive balls in the adhesive layer and defining a single layer, and electrically connecting the display panel and the electronic component, wherein the display panel includes a base layer, a pixel on the base layer, and including a pixel driving circuit which includes a silicon transistor having a first gate, an oxide transistor having a second gate above the silicon transistor, and a shielding electrode between the first gate and the second gate and overlapping the oxide transistor, and a light emission element which is electrically connected to the pixel driving circuit, a signal line overlapping the non-display region, including an end portion on a same layer as the first gate or the shielding electrode, and electrically connected to the pixel driving circuit, a signal pad electrically connected to the end portion, an intermediate insulation layer overlapping the pixel, and between the end portion and the signal pad, an upper insulation layer on the intermediate insulation layer, and having a contact hole defined thereon, and an upper auxiliary electrode including on the intermediate insulation layer, and a first portion exposed by the contact hole and a second portion covered by the upper insulation layer, wherein the signal pad includes an uppermost conductive pattern is on the upper auxiliary electrode, and electrically connected to the upper auxiliary electrode, and the electronic component includes a connection terminal is on the uppermost conductive pattern, and electrically connected to the uppermost conductive pattern through the conductive adhesive layer.

According to some embodiments, the conductive balls may include a first conductive ball overlapping the first portion and the connection terminal, a second conductive ball overlapping the second portion and the connection terminal, and a third conductive ball not overlapping the connection terminal, wherein a separation distance between a portion overlapping the first portion of the uppermost conductive pattern in a thickness direction of the display panel and the electronic component and the connection terminal is the same as or less than a diameter of the third conductive ball in the thickness direction.

According to some embodiments, a diameter of the first conductive ball in the thickness direction may be the same as or less than the diameter of the third conductive ball in the thickness direction.

According to some embodiments, the separation distance between the uppermost conductive pattern in the thickness direction of the display panel and the electronic component and the connection terminal may be 3 μm or less.

According to some embodiments, the uppermost conductive pattern may include a third portion corresponding to the first portion and a fourth portion corresponding to the second portion, wherein a height difference between the third portion and the fourth portion in the thickness direction of the display panel may be 1 μm or less.

According to some embodiments, the signal pad further include an intermediate conductive pattern between the upper auxiliary electrode and the uppermost conductive pattern, and electrically connecting the uppermost conductive pattern and the upper auxiliary electrode.

According to some embodiments, the upper insulation layer may have a first sub-contact hole overlapping the second portion, and the upper insulation layer and the intermediate insulation layer may have a second sub-contact hole overlapping the second portion, wherein the intermediate conductive pattern may be connected to the upper auxiliary electrode through the first sub-contact hole, and the intermediate conductive pattern may be connected to the end portion through the second sub-contact hole.

According to some embodiments, the display device may further include a lower auxiliary electrode between the end portion and the upper auxiliary electrode, and electrically connected to each of the end portion and the upper auxiliary electrode, wherein the intermediate insulation layer may include a first intermediate insulation layer which covers the end portion and a second intermediate insulation layer which covers the lower auxiliary electrode.

According to some embodiments, the signal pad may further include an intermediate conductive pattern between the upper auxiliary electrode and the uppermost conductive pattern, and electrically connecting each of the uppermost conductive pattern, the upper auxiliary electrode, and the lower auxiliary electrode, wherein the upper insulation layer may have a first sub-contact hole overlapping the second portion, the upper insulation layer and the second intermediate insulation layer may have a second sub-contact hole overlapping the second portion, and the upper insulation layer, the first intermediate insulation layer, and the second intermediate insulation layer may have a third sub-contact hole overlapping the second portion, wherein the intermediate conductive pattern may be connected to the upper auxiliary electrode through the first sub-contact hole, the intermediate conductive pattern may be connected to the lower auxiliary electrode through the second sub-contact hole, and the intermediate conductive pattern may be connected to the end portion through the third sub-contact hole.

### BRIEF DESCRIPTION OF THE DRAWINGS

The accompanying drawings are included to provide a further understanding of the inventive concept, and are incorporated in and constitute a part of this specification. The drawings illustrate aspects of some embodiments of the inventive concept and, together with the description, serve to explain principles of the inventive concept. In the drawings:

FIG. 1A is a perspective view of an electronic device according to some embodiments of the inventive concept;

FIG. 1B is an exploded perspective view of an electronic device according to some embodiments of the inventive concept;

FIG. 2 is a cross-sectional view of a display device according to some embodiments of the inventive concept;

FIG. 3 is a plan view of a display panel according to some embodiments of the inventive concept;

FIG. 4 is a cross-sectional view of a display panel according to some embodiments of the inventive concept;

FIG. 5 is a cross-sectional view of an input sensor according to some embodiments of the inventive concept;

FIG. 6 is an exploded perspective view for a pad region of a display device according to some embodiments of the inventive concept;

FIG. 7 is a perspective view illustrating a conductive adhesive layer according to some embodiments of the inventive concept;

FIG. 8 is a cross-sectional view of a portion of a pad region of a display device according to some embodiments of the inventive concept;

FIG. 9 is a cross-sectional view of an enlarged portion of a display device according to some embodiments of the inventive concept;

FIG. 10 is a view of an enlarged portion of a display device according to some embodiments of the inventive concept;

FIG. 11 is a view of an enlarged portion of a display device according to some embodiments of the inventive concept;

FIG. 12 is a view of an enlarged portion of a display device according to some embodiments of the inventive concept; and

FIG. 13 is a view of an enlarged portion of a display device according to some embodiments of the inventive concept.

### DETAILED DESCRIPTION

In the present disclosure, when an element (or a region, a layer, a portion, etc.) is referred to as being “on,” “connected to,” or “coupled to” another element, it means that the element may be directly on/connected to/coupled to the other element, or that a third element may be located therebetween.

Like reference numerals refer to like elements. Also, in the drawings, the thickness, the ratio, and the dimensions of elements are exaggerated for an effective description of technical contents. The term “and/or” includes any and all combinations of one or more of which associated elements may define.

It will be understood that, although the terms “first,” “second,” etc. may be used herein to describe various elements, these elements should not be limited by these terms. These terms are only used to distinguish one element from another. For example, a first element may be referred to as a second element, and a second element may also be referred to as a first element in a similar manner without departing the scope of rights of the present invention. The terms of a singular form may include plural forms unless the context clearly indicates otherwise.

In addition, terms such as “below,” “lower,” “above,” “upper,” and the like are used to describe the relationship of the elements shown in the drawings. The terms are used as a relative concept and are described with reference to the direction indicated in the drawings.

It should be understood that the term “comprise,” or “have” is intended to specify the presence of stated features, integers, steps, operations, elements, components, or combinations thereof in the disclosure, but do not preclude the presence or addition of one or more other features, integers, steps, operations, elements, components, or combinations thereof.

Unless otherwise defined, all terms (including technical and scientific terms) used herein have the same meaning as commonly understood by one of ordinary skill in the art to which the present invention pertains. It is also to be understood that terms defined in commonly used dictionaries should be interpreted as having meanings consistent with the meanings in the context of the related art, and are expressly defined herein unless they are interpreted in an ideal or overly formal sense.

Hereinafter, aspects of some embodiments of the present disclosure, a display device according to some embodiments will be described in more detail with reference to the accompanying drawings.

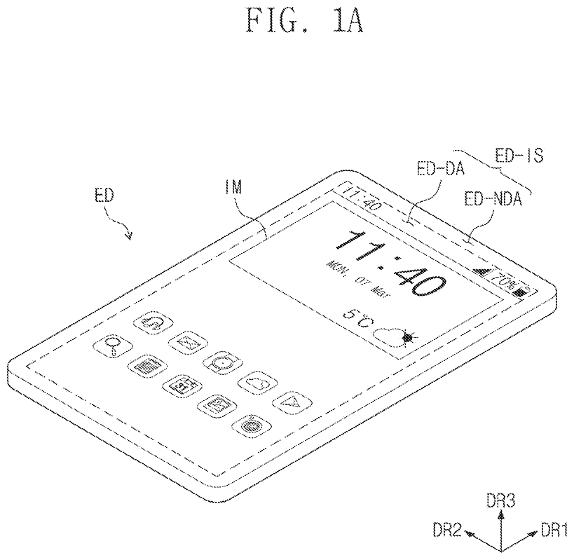

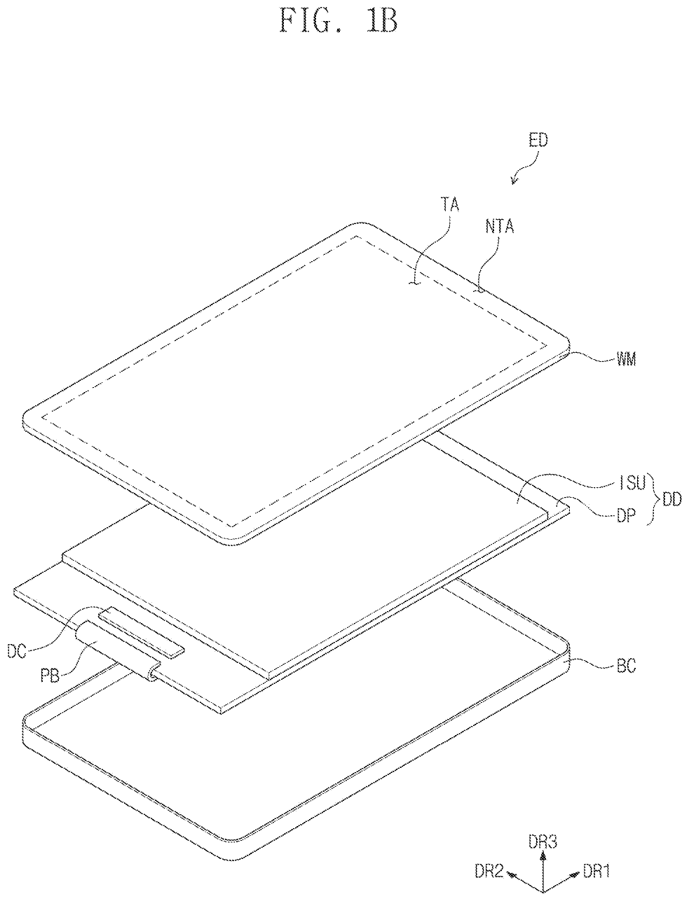

FIG. 1A is a perspective view of an electronic device ED according to some embodiments of the inventive concept. FIG. 1B is an exploded perspective view of the electronic device ED according to some embodiments of the inventive concept.

FIG. 1A and FIG. 1B illustrate a cell phone terminal as an example of the electronic device ED. The electronic device ED according to the present disclosure may be applicable to large-sized electronic devices such as televisions and monitors and also to small-and-medium-sized electronic devices such as tablets, car navigation systems, game consoles, and smart watches.

Referring to FIG. 1A, the electronic device ED may display an image IM through a display surface ED-IS. As an example of the image IM, icon images are illustrated. The display surface ED-IS is parallel to a plane defined by a first direction DR1 and a second direction DR2. The normal direction of the display surface ED-IS, that is, the thickness direction of the electronic device ED is indicated by a third direction DR3. In the present disclosure, “when viewed on a plane,” or “on a plane” may mean when viewed from the direction DR3. A front surface (or an upper surface) and a rear surface (or a lower surface) of each layer or unit described below are distinguished by the third direction DR3.

Also, the display surface ED-IS includes a display region ED-DA on which the image IM is displayed, and a non-display region ED-NDA adjacent to the display region ED-DA. The non-display region ED-NDA is a region on which an image is not displayed. However, the embodiments of the inventive concept are not limited thereto. The non-display region ED-NDA may be adjacent to any one side of the display region ED-DA, or may be omitted.

Referring to FIG. 1B, the electronic device ED may include a window WM, a display device DD, and a housing BC. The housing BC accommodates a display module DM, and may be coupled to the window WM. According to some embodiments, the electronic device ED may further include other electronic modules which are accommodated in the housing BC and electrically connected to the display device DD. For example, the electronic device ED may further include a main board, and c circuit module mounted on the main board, a camera module, a power module, etc.

The window WM is located in an upper portion of the display device DD, and may transmit an image provided from the display device DD to the outside. The window WM may include a transmissive region TA and a non-transmissive region NTA. The transmissive region TA overlaps the display region ED-DA, and may have a shape corresponding to the display region ED-DA.

The non-transmissive region NTA overlaps the non-display region ED-NDA, and may have a shape corresponding to the non-display region ED-NDA. The non-transmission region NTA may be a region having a relatively low light transmittance compared to the transmissive region TA. A bezel pattern may be located in some regions of a base layer, and a region in which a bezel pattern is located may be the non-transmissive region NTA, and a region in which a bezel pattern is not located may be the transmissive region TA. A base layer of the window WM may be composed of glass, sapphire, plastic, or the like. However, the embodiments of the inventive concept are not limited thereto, and in some embodiments the non-transmissive region NTA may be omitted.

The display device DD generates images, and may sense an external input. The display device DD includes a display panel DP and an input sensor ISU. According to some embodiments, the display device DD may further include a refection prevention member located on the input sensor ISU. The reflection prevention member may include a polarizer or a retarder, or may include a color filter and a black matrix.

According to some embodiments, the display panel DP may be a light emission type display panel, but is not limited to a particular type. For example, the display panel DP may be an organic light emission display panel or an inorganic light emission display panel. A light emission layer of the organic light emission display panel may include an organic light emission material. A light emission layer of the inorganic light emission display panel may include quantum dots, quantum rods, nano-LEDs, and the like. Hereinafter, the display panel DP is described as an organic light emission display panel.

The input sensor ISU may include any one among a capacitive sensor, an optical sensor, an ultrasonic sensor, and an electromagnetic induction sensor. The input sensor ISU may be formed on the display panel DP through a continuous process, or may be separately manufactured and then attached to an upper side of the display panel DP though an adhesive layer.

The display device DD may further include a driving chip DC and a circuit board PB. Embodiments in which the driving chip DC is mounted on the display panel DP is illustrated, but embodiments according to the present disclosure are not limited thereto. The driving chip DC may generate a driving signal required for the operation of the display panel DP on the basis a control signal transmitted from the circuit board PB. The circuit board PB bonded to the display panel DP may be bent and located on the rear surface of the display panel DP. The circuit board PB is located at one end of a base layer BL, and may be electrically connected to a circuit element layer DP-CL.

FIG. 1B illustrates embodiments in which the circuit board PB is bent, but the embodiments of the inventive concept are not limited thereto. A portion of the display panel DP may be bent such that the driving chip DC faces downward. A non-display region of the display panel DP may be bent.

In the above, a cell phone terminal has been described as the electronic device ED, but in the present disclosure, it is sufficient that if the electronic device ED includes two or more bonded electronic components. The display panel DP and the driving chip DC mounted on the display panel DP respectively correspond to different electronic components, and the electronic device ED may be composed of these two only. The display panel DP and the circuit board PB connected to the display panel DP may constitute the electronic device ED, and a main board and an electronic module mounted on the main board may constitute the electronic device ED. Hereinafter, focusing on a bonding structure between the display panel DP and the driving chip DC mounted on the display panel DP, the electronic device ED according to the present disclosure will be described.

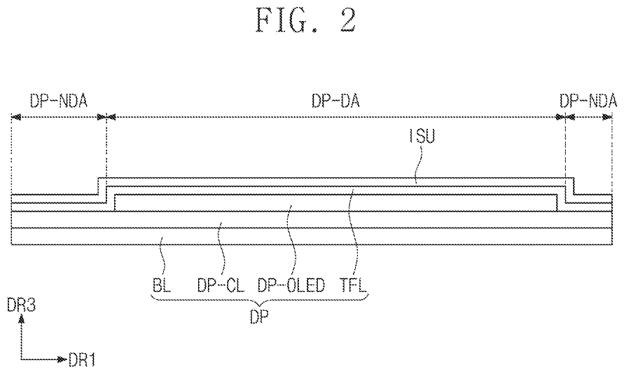

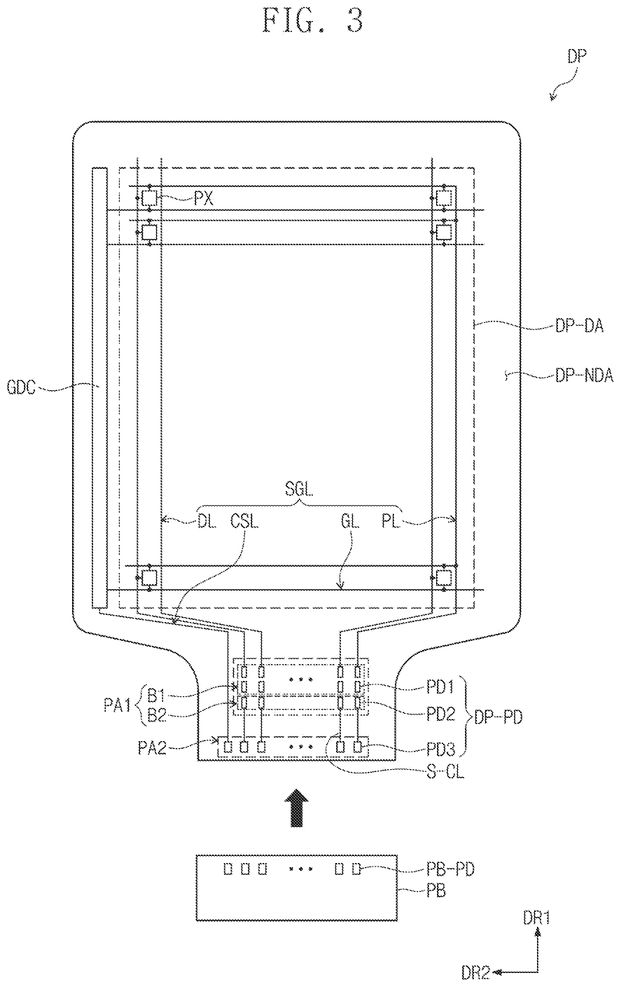

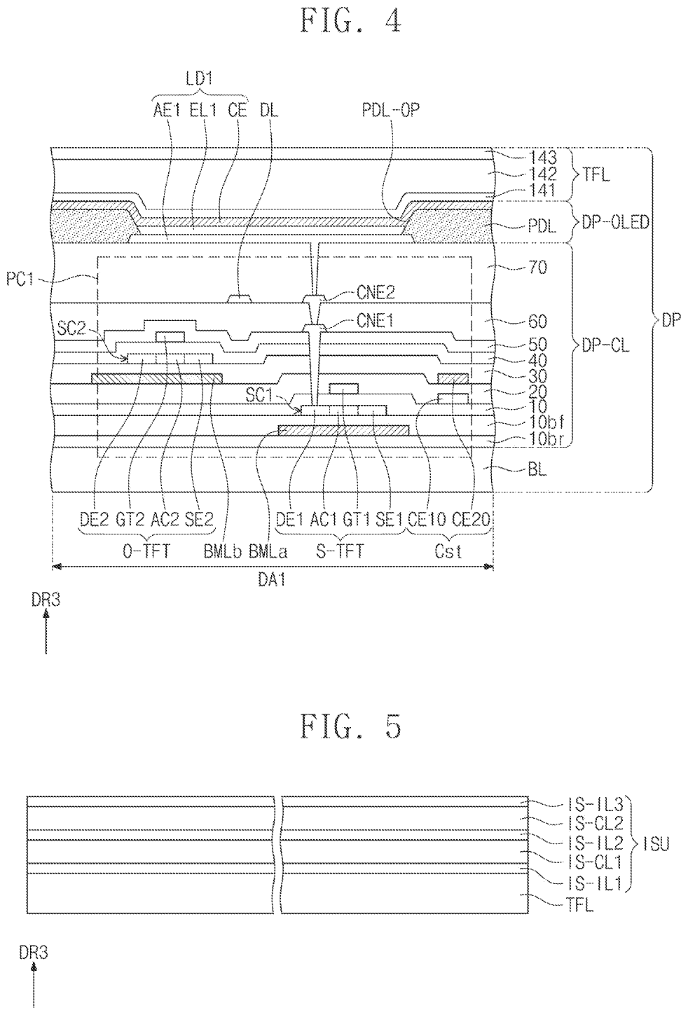

FIG. 2 is a cross-sectional view of the display device DD according to some embodiments of the inventive concept. FIG. 3 is a plan view of the display panel DP according to some embodiments of the inventive concept. FIG. 4 is a cross-sectional view of the display panel DP according to some embodiments of the inventive concept.

Referring to FIG. 2, the display panel DP includes the base layer BL, the circuit element layer DP-CL located on the base layer BL, a display element layer DP-OLED, and an encapsulation layer TFL. The input sensor ISU may be located on the encapsulation layer TFL.

The display panel DP includes a display region DP-DA and a non-display region DP-NDA. The display region DP-DA of the display panel DP corresponds to the display region ED-DA illustrated in FIG. 1A or the transmissive region TA illustrated in FIG. 1B, and the non-display region DP-NDA corresponds to the non-display region ED-NDA illustrated in FIG. 1A or the non-transmissive region NTA illustrated in FIG. 1B.

The base layer BL may include at least one plastic film. The base layer BL may include a synthetic resin film. A synthetic resin layer may include a thermosetting resin. Particularly, the synthetic resin layer may be a polyimide-based resin layer, and the material thereof is not particularly limited. The synthetic resin layer may include at least any one of an acrylic resin, a methacrylic resin, polyisoprene, a vinyl-based resin, an epoxy-based resin, a urethane-based resin, a cellulose-based resin, a siloxane-based resin, a polyamide-based resin, or a perylene-based resin. In addition, the base layer may include a glass substrate, a metal substrate, an organic/inorganic composite substrate, or the like.

The circuit element layer DP-CL may include at least one insulation layer and a circuit element. The insulation layer may include at least one inorganic layer and at least one organic layer. The circuit element may include signal lines, a pixel driving circuit, and the like. An insulation layer, a semiconductor layer, and a conductive layer are formed by processes such as coating, and deposition. Thereafter, the insulation layer, the semiconductor layer, and the conductive layer may be selectively patterned through photolithography, and etching. Through such processes, a semiconductor pattern, a conductive pattern, a signal line, and the like are formed. Patterns located on the same layer are formed through the same process. Hereinafter, when patterns are formed through the same process, it means that the patterns include the same material, and include the same laminate structure.

The display element layer DP-OLED may include an organic light emission element. The display element layer DP-OLED may further include an organic layer such as a pixel definition film.

The encapsulation layer TFL may seal the display element layer DP-OLED. The encapsulation layer TFL may include a laminate structure of an inorganic layer/an organic layer/an inorganic layer. The encapsulation layer TFL may protect the display element layer DP-OLED from foreign substances such as moisture, oxygen, and dust particles.

According to some embodiments, an encapsulation substrate may be provided instead of the encapsulation layer TFL. In this case, the encapsulation substrate opposes the base layer BL, and between the encapsulation substrate and the base layer BL, the circuit element layer DP-CL and the display element layer DP-OLED may be located.

The input sensor ISU may be directly located on the display panel DP. As used herein, “Component A is directly located on Component B” means that no adhesive layer is located between Component A and Component B. According to some embodiments, the input sensor ISU may be manufactured in a continuous process with the display panel DP. However, the embodiments of the inventive concept are not limited thereto, and the input sensor ISU may be provided as an individual panel, and be coupled to the display panel DP through an adhesive layer. According to some embodiments, the input sensor ISU may be omitted.

Referring to FIG. 3, the display panel DP may include a plurality of pixels PX, a gate driving circuit GDC, a plurality of signal lines SGL, and a plurality of signal pads DP-PD.

The pixels PX are located in the display region DP-DA. Each of the pixels PX includes an organic light emission element and a pixel driving circuit connected thereto. The gate driving circuit GDC sequentially outputs gate signals to a plurality of gate lines GL. A transistor of the driving circuit GDC may be formed through the same process as the process of a transistor of the pixel PX, for example, a Low Temperature Polycrystalline Silicon (LTPS) process or a Low Temperature Polycrystalline Oxide (LTPO) process. The display panel DP may further include another driving circuit which provides a light emission control signal to the pixels PX.

The signal lines SGL include the gate lines GL, data lines DL, a power line PL, and a control signal line CSL. The gate lines GL are each connected to a corresponding pixel PX among the pixels PX, and the data lines DL are each connected to a corresponding pixel PX among the pixels PX. The power line PL is connected to the pixels PX. The control signal line CSL may provide control signals to a scan driving circuit.

The signal lines SGL overlap the display region DP-DA and the non-display region DP-NDA. The signal lines SGL may each include a pad portion and a line portion. The line portion overlaps the display region DP-DA and the non-display region DP-NDA. The pad portion is connected to an end of the line portion. The pad portion may overlap a pad region to be described later.

The plurality signal pads DP-PD may include first pads PD1, second pads PD2, and third pads PD3. A region in which the first pads PD1 and the second pads PD2 are located may be defined as a first pad region PA1, and a region in which third pads PD3 are located may be defined as a second pad region PA2. The first pad region PA1 is a region bonded to the driving chip DC (see FIG. 1B), and the second pad region PA2 is a region bonded to the circuit board PB (see FIG. 1B). The pad region PA1 may include a first region B1 in which the first pads PD1 are located, and a second region B2 in which the second pads PD2 are located. The first pad region PA1 and the second pad region PA2 are located in the non-display region DP-NDA. Each of some of the first pads PD1 may be connected to a corresponding data line DL.

The first pad region PA1 and the second pad region PA2 may be spaced apart from each other in the second direction DR2. The second pads PD2 and the third pads PD3 may be connected through connection signal lines S-CL. Two pad rows are illustrated in the first region B1, but the embodiments of the inventive concept are not limited thereto, and more pad rows may be located therein. The third pads PD3 may be bonded to circuit pads PB-PD of the circuit board PB. The bonding structure between the third pads PD3 and the circuit pads PB-PD of the circuit board PB may have the same as or different from the bonding structure between the first pad PD1 or the second pad PD2 with a bump of the driving chip DC, which will be described later.

Referring to FIG. 4, a barrier layer 10br may be located on a base layer 110. The barrier layer 10br prevents or reduces instances of foreign substances being introduced from the outside. The barrier layer 10br may include at least one inorganic layer. The barrier layer 10br may include a silicon oxide layer and a silicon nitride layer. Each of these may be provided in plurality, and silicon oxide layers and silicon nitride layers may be alternately laminated.

On the barrier layer 10br, a first shielding electrode BMLa may be located. The first shielding electrode BMLa may include a metal. The first shielding electrode BMLa may include molybdenum (Mo) with good heat resistance, an alloy containing molybdenum, titanium (Ti), or an alloy containing titanium. The first shielding electrode BMLa may receive a bias voltage. The first shielding electrode BMLa may receive a first power voltage ELVDD. The first shielding electrode BMLa may stop an electrical potential due to polarization from affecting a silicon transistor S-TFT. The first shielding electrode BMLa may stop external light from reaching the silicon transistor S-TFT. According to some embodiments, the first shielding electrode BMLa may be a floating electrode in an isolated form from another electrode or line.

A buffer layer 10bf may be located on the barrier layer 10br. The buffer layer 10bf may prevent or reduce a phenomenon in which metal atoms or impurities from the base layer 110 diffuse into a first semiconductor pattern SC1 on an upper side. The buffer layer 10bf may include at least one inorganic layer. The buffer layer 10bf may include a silicon oxide layer and a silicon nitride layer.

The first semiconductor pattern SC1 may be located on the buffer layer 10bf. The first semiconductor pattern SC1 may include a silicon semiconductor. For example, the silicon semiconductor may include amorphous silicon, polycrystalline silicon, and the like. For example, the first semiconductor pattern SC1 may include low-temperature polysilicon.

FIG. 4 illustrates only a portion of the first semiconductor pattern SC1, and the first semiconductor pattern SC1 may be further located in other regions. The first semiconductor pattern SC1 may be arranged across the pixels according to a specific rule. The first semiconductor pattern SC1 may have different electrical properties depending on whether or not doped. The first semiconductor pattern SC1 may include a first region having high conductivity and a second region having low conductivity. The first region may be doped with an N-type dopant or a P-type dopant. A P-type transistor may include a doped region which has been doped with the P-type dopant, and an N-type transistor may include a doped region which has been doped with the N-type dopant. The second region may be a non-doped region or a region doped to a concentration lower than that of the first region.

The conductivity of the first region may be greater than the conductivity of the second region, and the first region may substantially serve as an electrode or a signal. The second region may substantially correspond to a channel region (or an active region) of a transistor. In other words, a portion of the first semiconductor pattern SC1 may be a channel of a transistor, and another portion thereof may be a source or a drain of the transistor, and the other portion thereof may be a connection electrode or a connection signal line.

A source region SE1, a channel region AC1 (or an active region), and a drain region DE1 of the silicon transistor S-TFT may be formed from the first semiconductor pattern SC1. The source region SE1 and the drain region DE1 may be extended in opposite directions from the channel region AC1 on a cross section.

A first insulation layer 10 may be located on the buffer layer 10bf. The first insulation layer 10 may cover the first semiconductor pattern SC1. The first insulation layer 10 may be an inorganic layer. The first insulation layer 10 may be a single-layered silicon oxide layer. An inorganic layer of a circuit layer 120 to be described later, not the first insulation layer 10, may have a single-layered or multi-layered structure, and may include at least one of the above-described materials, but the embodiments of the inventive concept are not limited thereto.

A first gate GT1 of the silicon transistor S-TFT may be located on the first insulation layer 10. The first gate GT1 may be a portion of a metal pattern. The first gate GT1 overlaps the channel region AC1. In a process of doping the first semiconductor pattern SC1, the gate GT1 may be a mask. A first electrode CE10 of a storage capacitor Cst may be located on the first insulation layer 10. Unlike what is illustrated in FIG. 4, the first electrode CE10 may have a shape of a single body with the first gate GT1.

A second insulation layer 20 may be located on the first insulation layer 10, which may cover the first gate GT1. According to some embodiments, an upper electrode overlapping the first gate GT1 may be located on the second insulation layer 20. A second electrode CE20 overlapping the first electrode CE10 may be located on the second insulation layer 20.

A second shielding electrode BMLb may be located on the second insulation layer 20. The second shielding electrode BMLb may be arranged to correspond to a lower portion of an oxide transistor O-TFT. According to some embodiments, the first shielding electrode BMLa may be extended to a lower portion of the oxide transistor O-TFT and replace the second shielding electrode BMLb.

A third insulation layer 30 may be located on the second insulation layer 20. A second semiconductor pattern SC2 may be located on the third insulation layer 30. The second semiconductor pattern SC2 may include a channel region AC2 of the oxide transistor O-TFT. The second semiconductor pattern SC2 may include an oxide semiconductor. The second semiconductor pattern SC2 may include a transparent conductive oxide (TCO) such as an indium tin oxide (ITO), an indium zinc oxide (IZO), an indium gallium zinc oxide (IGZO), a zinc oxide (ZnOx), an indium oxide (In2O3), or the like.

The oxide semiconductor may include a plurality of regions which are distinguished depending on whether a transparent conductive oxide has been reduced or not. A region in which the transparent conductive oxide has been reduced (hereinafter, a reduction region) has greater conductivity than a region in which the transparent conductive oxide has not been reduced (hereinafter, a non-reduction region). The reduction region substantially serves as a source/drain or signal line of a transistor. The non-reduction region substantially corresponds to a semiconductor region (or channel) of a transistor. In other words, a partial region of the second semiconductor pattern SC2 may be a semiconductor region of a transistor, another partial region thereof may be a source region/drain region of the transistor, and the other partial region thereof may be a signal transmissive region.

A fourth insulation layer 40 may be located on the third insulation layer 30. As illustrated in FIG. 4, the fourth insulation layer 40 overlaps a gate GT2 of the oxide transistor O-TFT, and may be an insulation pattern exposed by a source region SE2 and a drain region DE2 of the oxide transistor O-TFT. According to some embodiments, the fourth insulation layer 40 commonly overlaps a plurality of pixels, and may cover the second semiconductor pattern SC2.

A second gate GT2 of the oxide transistor O-TFT may be located on the fourth insulation layer 40. The second gate GT2 of the oxide transistor O-TFT may be a portion of a metal pattern. The second gate GT2 of the oxide transistor O-TFT overlaps the channel region AC2.

A fifth insulation layer 50 may be located on the fourth insulation layer 40, and the fifth insulation layer 50 may cover the second gate GT2. The first insulation layer 10 to the fifth insulation layer 50 may each be an insulation layer.

A first connection electrode CNE1 may be located on the fifth insulation layer 50. The first connection electrode CNE1 may be connected to the drain region DE1 of the silicon transistor S-TFT through a contact hole passing through the first to fifth insulation layers 10, 20, 30, 40, and 50.

A sixth insulation layer 60 may be located on the fifth insulation layer 50. A second connection electrode CNE2 may be located on the sixth insulation layer 60. The second connection electrode CNE2 may be connected to the first connection electrode CNE1 through a contact hole passing through the sixth insulation layer 60.

The data line DL may be located on the sixth insulation layer 60. A seventh insulation layer 70 is located on the sixth insulation layer 60, and may cover the second connection electrode CNE2 and the data line DL. The sixth insulation layer 60 and the seventh insulation layer 70 may each be an organic layer.

A first light emission element LD1 may include an anode AE1 (or a first electrode), a light emission layer EL1, and a cathode CE (or a second electrode). A cathode CE of a second light emission element LD2 and a cathode CE of a third light emission element LD3 to be described later may have a shape of a single body with the cathode CE of the first light emission element LD1. That is, the cathode CE may be commonly provided to the first light emission element LD1, the second light emission element LD2, and the third light emission element LD3.

The anode AE1 of the first light emission element LD1 may be located on the seventh insulation layer 70. The anode AE1 may be a (semi)transmissive electrode or a reflective electrode. The pixel definition film PDL may be located on the seventh insulation layer 70. The pixel definition film PDP includes the same material, and may be formed through the same process. The pixel definition film PDL may have properties of absorbing light, and for example, the pixel definition film PDL may have a black color. The pixel definition PDP may include a black coloring agent. The black coloring agent may include a black dye and a black pigment. The black coloring agent may include a metal such as carbon black or chromium, or an oxide thereof. The pixel definition film PDL may correspond to a light blocking pattern having light blocking properties.

The pixel definition film PDL may cover a portion of the anode AE1. For example, the pixel definition film PDL may have an opening PDL-OP defined thereon, which exposes a portion of the anode AE1.

According to some embodiments, a hole control layer may be located between the anode AE1 and the light emission layer EL1. The hole control layer includes a hole transport layer, and may further include a hole injection layer. An electron control layer may be located between the light emission layer EL1 and the cathode CE. The electron control layer includes an electron transport layer, and may further include an electron injection layer. The hole control layer and the electron control layer may be commonly formed in the plurality of pixels PX (see FIG. 3) using an open mask.

The encapsulation layer TFL may be located on the display element layer DP-OLED. The encapsulation layer TFL may include an inorganic layer 141, an organic layer 142, and an inorganic layer 143 which are sequentially laminated, but layers constituting the encapsulation layer TFL are not limited thereto.

The inorganic layers 141 and 143 may protect the display element layer DP-OLED from moisture and oxygen, and the organic layer 142 may protect the display element layer DP-OLED from foreign substances such as dust particles. The inorganic layers 141 and 143 may include a silicon nitride layer, a silicon oxynitride layer, a silicon oxide layer, a titanium oxide layer, an aluminum oxide layer, or the like. The organic layer 142 may include an acrylic organic layer, but is not limited thereto.

FIG. 5 is a cross-sectional view of the input sensor ISU according to some embodiments of the inventive concept. Referring to FIG. 5, the input sensor ISU may include a first insulation layer IS-IL1 (hereinafter, a first sensing insulation layer), a first conductive pattern layer IS-CL1, a second insulation layer IS-IL2 (hereinafter, a second sensing insulation layer), a second conductive pattern layer IS-CL2, and a third insulation layer IS-IL3 (hereinafter, a third sensing insulation layer). The first sensing insulation layer IS-IL1 may be directly located on the encapsulation layer TFL.

According to some embodiments, the first sensing insulation layer IS-IL1 and/or the third sensing insulation layer IS-IL3 may be omitted. When the first sensing insulation layer IS-IL1 is omitted, the first conductive pattern layer IS-CL1 may be located on an insulation layer on the uppermost side of the encapsulation layer TFL.

The third sensing insulation layer IS-IL3 may be replaced with an adhesive layer or an insulation layer of a refection prevention member located on the input sensor ISU.

The first conductive pattern layer IS-CL1 may include first conductive patterns, and the second conductive pattern layer IS-CL2 may include second conductive patterns. Hereinafter, the first conductive pattern layer IS-CL1 and the first conductive patterns are referred to by the same reference numerals, and the second conductive pattern layer IS-CL2 and the second conductive patterns are referred to by the same reference numerals.

The first conductive patterns IS-CL1 and the second conductive patterns IS-CL2 may each have a single-layered structure, or a multi-layered structure in which patterns are laminated along the third direction DR3. A conductive layer of a multi-layered structure may include at least two of transparent conductive layers and metal layers. The conductive pattern of the multi-layered structure may include metal layers including different metals from each other. A transparent conductive layer may include an indium tin oxide (ITO), an indium zinc oxide (IZO), a zinc oxide (ZnO), an indium tin zinc oxide (ITZO), PEDOT, a metal nanowire, and graphene. A metal layer may include molybdenum, silver, titanium, copper, aluminum, or an alloy thereof.

According to some embodiments, each of the first sensing insulation layer IS-IL1 to the third sensing insulation layer IS-IL3 may include an inorganic layer or an organic layer. According to some embodiments, the first sensing insulation layer IS-IL1 to the third sensing insulation layer IS-IL3 may each include an inorganic layer. The inorganic layer may include silicon oxide, silicon nitride, or silicon oxynitride.

According to some embodiments, at least one of the first sensing insulation layer IS-IL1 to the third sensing insulation layer IS-IL3 may be an organic layer. For example, the third sensing insulation layer IS-IL3 may include an organic layer. The organic layer may include at least one of an acrylic resin, a methacryl-based resin, polyisoprene, a vinyl-based resin, an epoxy-based resin, a urethane-based resin, a cellulose-based resin, a siloxane-based resin, a polyimide-based resin, a polyamide-based resin, or a perylene-based resin.

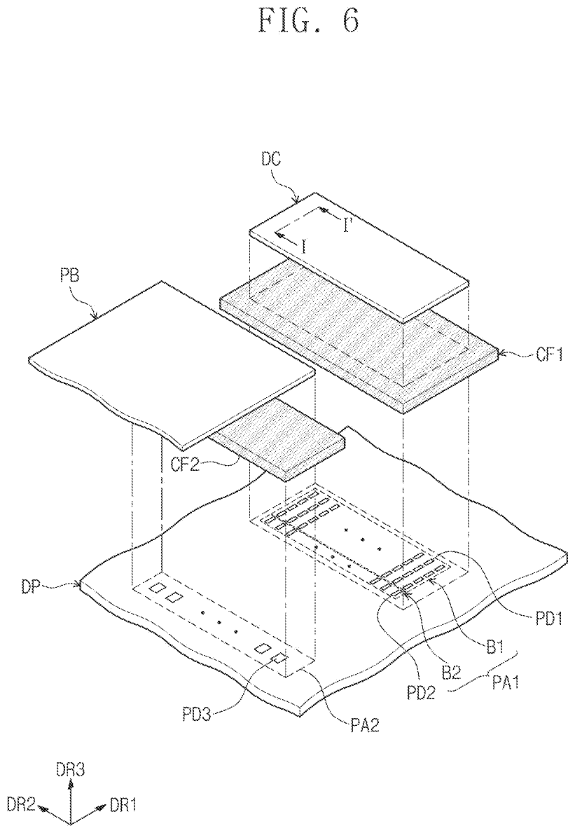

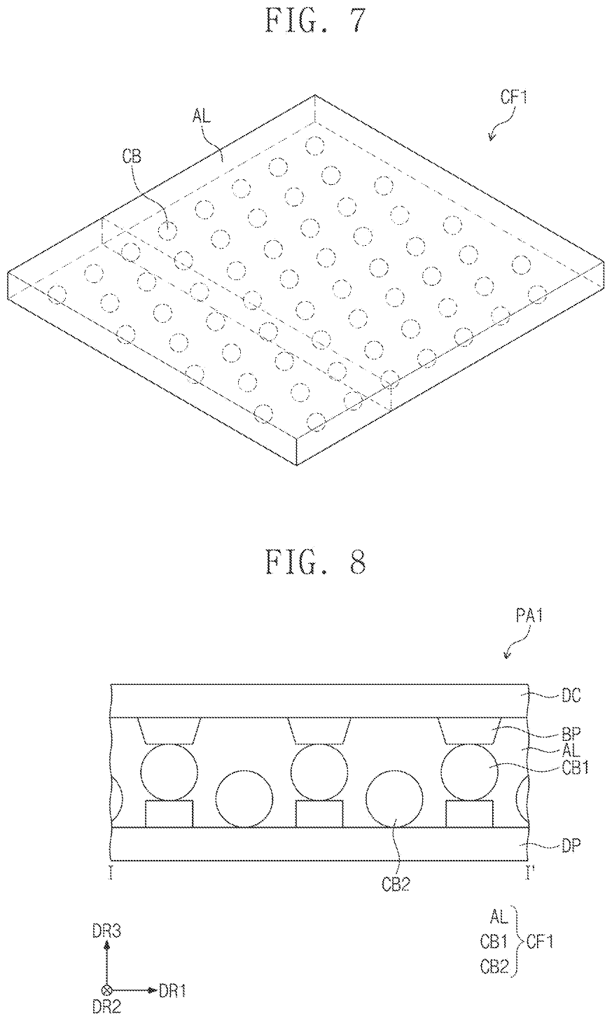

FIG. 6 is an exploded perspective view for a pad region of a display device according to some embodiments of the inventive concept. FIG. 7 is a perspective view illustrating a conductive adhesive layer according to some embodiments of the inventive concept. FIG. 8 is a cross-sectional view of a portion of a pad region of a display device according to some embodiments of the inventive concept.

Referring to FIG. 6 to FIG. 8, the driving chip DC may be bonded to the first pad region PA1 through a first conductive adhesive layer CF1, and the circuit board PB may be bonded to the second pad region PA2 through a second conductive adhesive layer CF2. As illustrated in FIG. 7, the first conductive adhesive layer CF1 may include an adhesive layer AL and a plurality of conductive balls CB mixed with the adhesive layer AL and defining a single layer. The conductive balls CB may be aligned in a set or predetermined form. Meanwhile, the description for the first conductive adhesive layer CF1 may be equally applied to the second conductive adhesive layer CF2.

The driving chip DC and the circuit board PB may each include connection terminals which are electrically connected to each of the pads PD1, PD2, and PD3. The driving chip DC may include first bumps respectively and electrically connected to the first pads PD1, and second bumps respectively and electrically connected to the second pads PD2. The circuit board PB may include signal pads respectively and electrically connected to the third pads PD3.

The driving chip DC receives first signals from the outside through the second pads PD2 and the second bumps. The driving chip DC provides second signals generated on the basis of the first signals to the first pads PD1 through the first bumps. For example, the driving chip DC may include a data driving circuit. A first signal may be an image signal which is a digital signal applied from the outside, and a second signal may be a data signal which is an analogue signal. The driving chip DC generates an analogue voltage corresponding to a gray scale value of the image signal. The data signal is provided to the pixel PX through the data line DL illustrated in FIG. 3. The circuit board PB may provide an image signal, a driving voltage, and other control signals to the driving chip DC.

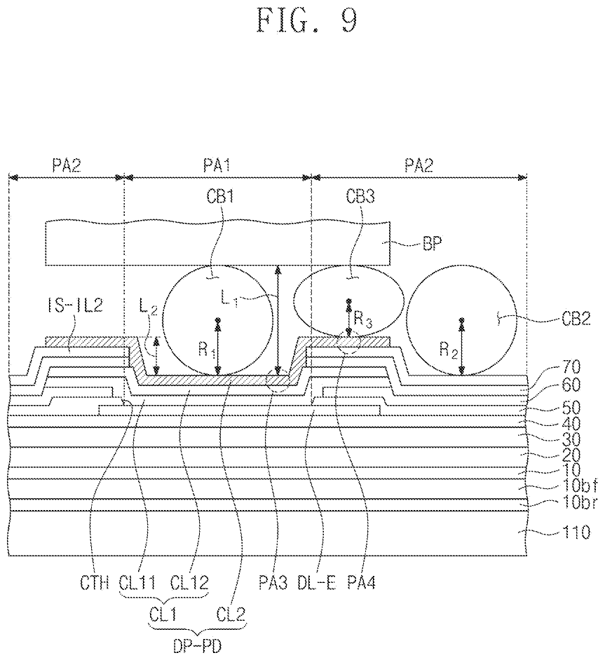

FIG. 9 is a cross-sectional view of an enlarged portion of a display device according to some embodiments of the inventive concept. In FIG. 9, a signal pad DP-PD may be any one among the first to third pads PD1 to PD3 illustrated in FIG. 6.

Referring to FIG. 9, according to some embodiments, an end portion DL-E may be located on the lower insulation layers 10 to 40. The end portion DL-E may be located on the fourth insulation layer 40. The end portion DL-E may be located on the same layer as the layer on which the second gate GT2 (see FIG. 4) is located. The end portion DL-E may be exposed by a contact hole CTH defined on the fifth insulation layer 50 (an upper insulation layer). The end portion DL-E may include a first portion PA1 exposed by the contact hole CTH and a second portion PA2 covered by the upper insulation layer 50.

The signal pad DP-PD may include an uppermost conductive pattern CL2 located on the end portion DL-E. The uppermost conductive pattern CL2 may be electrically connected to the end portion DL-E. Meanwhile, the uppermost conductive pattern CL2 may include the same material as the material of at least one of the conductive pattern layers IS-CL1 or IS-CL2 of the input sensor ISU illustrated in FIG. 5.

The electronic components DC and PB (see FIG. 6) may be located on the uppermost conductive pattern CL2. The electronic components DC and PB (see FIG. 6) may include a connection terminal BP electrically connected to the uppermost conductive pattern CL2 through the conductive adhesive layers CF1 and CF2 (see FIG. 6). Hereinafter, an electronic component is described as the driving chip DC (see FIG. 6) and the connection terminal BP is described as a first bump of the driving chip DC (see FIG. 6), and descriptions thereof may be equally applied to a case in which the electronic component PB is the driving chip DC (see FIG. 6) and the connection terminal BP is a second bump of the driving chip (see FIG. 6) and to a case in which the electronic component is the circuit board PB, and the connection terminal BP is a third bump of the circuit board PB.

Conductive balls CB1, CB2, and CB3 may be located between the uppermost conductive pattern CL2 and a bump BP. The conductive balls CB1, CB2, and CB3 may include a first conductive ball CB1 overlapping the first portion PA1 and the bump BP, a second conductive ball CB2 overlapping the second portion PA2 and the bump BP, and a third conductive ball CB3 not overlapping the bump BP. The third conductive layer CB3 may be a conductive ball in a non-compressed state. The second conductive ball CB2 may be compressed by pressure applied in the third direction DR3, and have an elliptical shape in which a diameter in the first direction DR1 is longer than a diameter in the third direction DR3.

The uppermost conductive pattern CL2 may include a third portion PA3 overlapping the first portion PA1 and a fourth portion PA4 overlapping the second portion PA2. A separation distance L1 between the third portion PA3 and the bump BP in the third direction DR3 may be the same as or less than a diameter R2 of the second conductive ball CB2. For example, the separation distance L1 between the third portion PA3 and the bump BP in the third direction DR3 may be 3 μm or less. By adjusting the separation distance L1 between the third portion PA3 and the bump BP in the third direction DR3 to be equal to or less than the diameter R2 of the second conductive ball CB2, pressure applied to the fourth portion PA4 by the second conductive ball CB2 may be reduced. That is, by adjusting the separation distance L1 between the third portion PA3 and the bump BP in the third direction DR3 to be equal to or less than the diameter R2 of the second conductive ball CB2, the breakage of the fourth portion PA4 caused by the pressure of the second conductive ball CB2 may be prevented or reduced.

The smaller the height difference L2 between the third portion PA3 and the fourth portion PA4 in the third direction DR3, the smaller the pressure required to allow the conductive balls CB1 and CB2 to contact the signal pad DP-PD. Specifically, the smaller the height difference L2 between the third portion PA3 and the fourth portion PA4 in the third direction DR3, the smaller the pressure applied to the fourth portion PA4 from the second conductive ball CB2, when the first conductive ball CB1 is brought into close contact with the third portion PA3. That is, as the height difference L2 between the third portion PA3 and the fourth portion PA4 becomes smaller, the breakage of the fourth portion PA4 caused by the pressure of the second conductive ball CB2 may be prevented or reduced. For example, a height difference between the third portion PA3 and the fourth portion PA4 may be 1 μm or less.

According to some embodiments, the signal pad DP-PD may further include an intermediate conductive pattern CL1. The intermediate conductive pattern CL1 may be located between the uppermost conductive pattern CL2 and the end portion DL-E. The intermediate conductive pattern CL1 may electrically connect the uppermost conductive pattern CL2 and the end portion DL-E.

According to some embodiments, the intermediate conductive pattern CL1 may include a first intermediate conductive pattern CL11 adjacent to the end portion DL-E, and a second intermediate conductive pattern CL12 located between the first intermediate conductive pattern CL11 and the uppermost conductive pattern CL2. The first intermediate conductive pattern CL11 may electrically connect the end portion DL-E and the second intermediate conductive pattern CL12. The second intermediate conductive pattern CL12 may electrically connect the uppermost conductive pattern CL2 and the first intermediate conductive pattern CL11.

The first intermediate conductive pattern CL11 and the second intermediate conductive pattern CL12 may be located on the upper insulation layer 50. Meanwhile, the embodiments may further include a seventh insulation layer 70 (hereinafter, a second organic layer) located on the upper insulation layer 50 in the pad regions PD1/PD2. In addition, the embodiments may further include the second sensing insulation layer IS-IL2 located in an upper portion of the second organic layer 70. The first intermediate conductive pattern CL11 and the second intermediate conductive pattern CL12 may be located between the upper insulation layer 50 and the second organic layer 70. The first intermediate conductive pattern CL11 and the first connection electrode CNE1 may include the same material.

The first intermediate conductive pattern CL11 and the second intermediate conductive pattern CL12 may be located between the fifth insulation layer 50 and the seventh insulation layer 70. The first intermediate conductive pattern CL11 and the first connection electrode CNE1 may include the same material. The second intermediate conductive pattern CL12 and the second connection electrode CNE2 may include the same material.

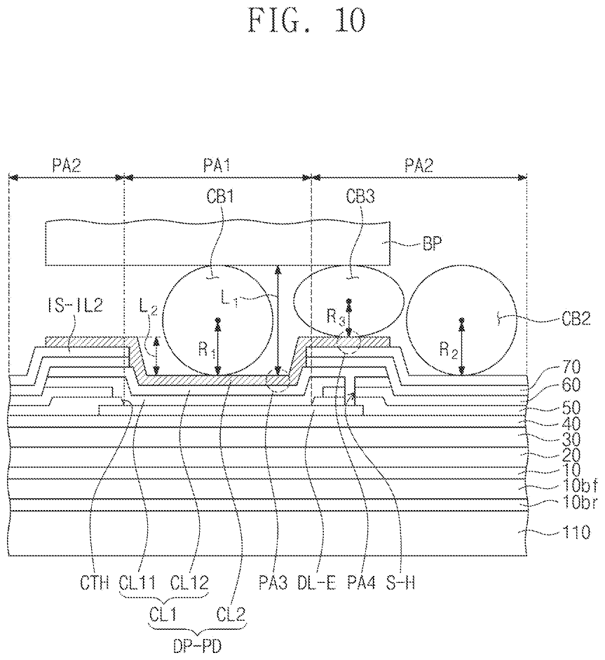

Hereinafter, referring to FIG. 10 to FIG. 13, a display device according to some embodiments will be described in more detail. The same contents as those described above with reference to FIG. 1 to FIG. 9 will not be described again. Instead, differences will be mainly described.

FIG. 10 is a view of an enlarged portion of a display device according to some embodiments of the inventive concept. The display device illustrated in FIG. 10 is different from the display device described with reference to FIG. 1 to FIG. 9 in that an upper insulation layer further includes a sub-contact hole.

Referring to FIG. 10, according to some embodiments, the upper insulation layer 50 may have a sub-contact hole S-H in a portion overlapping the second portion PA2. The second intermediate conductive pattern CL12 may be connected to the end portion DL-E through the sub-contact hole S-H.

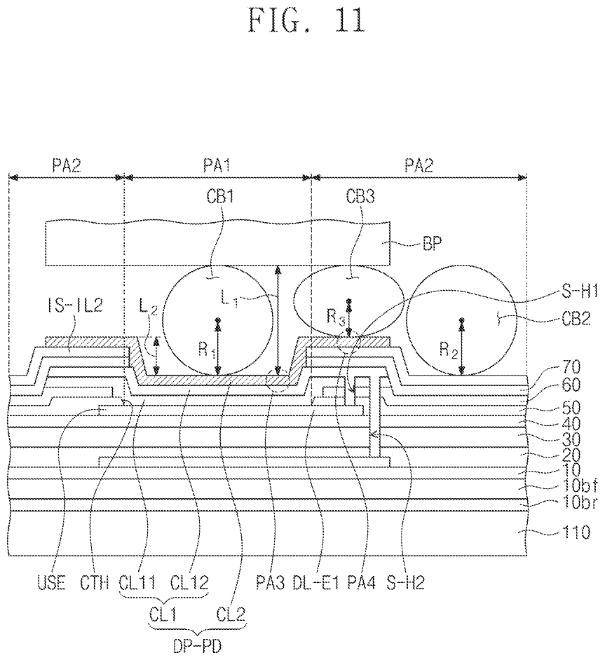

FIG. 11 is a view of an enlarged portion of a display device according to some embodiments of the inventive concept. The display device illustrated in FIG. 11 is different from the display device described with reference to FIG. 1 to FIG. 9 in that an end portion and a first gate are located on the same layer, and that an upper auxiliary electrode is further included.

Referring to FIG. 11, according to some embodiments, an end portion DL-E1 may be located on a first insulation layer 10 (hereinafter, a lower insulation layer). The end portion DL-E1 and the first gate GT1 (see FIG. 4) may be located on the same layer.

According to some embodiments, the second to fourth insulation layers 20 to 40 (hereinafter, intermediate insulation layers) may be located on the end portion DL-E1. A fifth insulation layer 50 (hereinafter, an upper insulation layer) may be located on the intermediate insulation layers 20 to 40. On the upper insulation layer 50, a contact hole CTH may be defined.

Some embodiments may include an upper auxiliary electrode USE located on the intermediate insulation layers 20 to 40. FIG. 11 illustrates the intermediate insulation layers 20 to 40 as a plurality of layers, but the intermediate insulation layers 20 to 40 may be one layer.

The upper auxiliary electrode USE may include a first portion PA1 exposed by the contact hole CTH and a second portion PA2 covered by the upper insulation layer 50. An uppermost conductive pattern CL2 may be electrically connected to the upper auxiliary electrode USE.

According to some embodiments, the upper insulation layer 50 may have a first sub-contact hole S-H1 overlapping the second portion PA2. The upper insulation layer 50 and the intermediate insulation layers 20 to 40 may have a second sub-contact hole S-H2 overlapping the second portion PA.

Meanwhile, some embodiments may further include an intermediate conductive pattern CL1 located between the uppermost conductive pattern CL2 and the upper auxiliary electrode USE. The uppermost conductive pattern CL2 may be electrically connected to the upper auxiliary electrode USE through the intermediate conductive pattern CL1.

The intermediate conductive pattern CL1 may be connected to the upper auxiliary electrode USE through the first sub-contact hole S-H1. The intermediate conductive pattern CL1 may be connected to the end portion DL-E1 through the second sub-contact S-H2.

Meanwhile, the intermediate conductive pattern CL1 may include a first intermediate conductive pattern CL11 and a second intermediate conductive pattern CL12 located on the first intermediate conductive pattern CL11. The first intermediate conductive pattern CL11 may be connected to the upper auxiliary electrode USE through the first sub-contact hole S-H1. The first intermediate conductive pattern CL11 may be connected to the end portion DL-E1 through the second sub-contact S-H2.

The display device according to some embodiments as illustrated in FIG. 11 includes the upper auxiliary electrode USE, and thus, may reduce a separation distance L1 between a third portion PA3 and a bump BP in a third direction DR3. For example, the separation distance L1 between the third portion PA3 and the bump BP in the third direction DR3 may be 3 μm or less. In addition, some embodiments may include the upper auxiliary electrode USE, and thus, may reduce a height difference L2 between a third portion PA3 and a fourth portion PA4. For example, the height difference L2 between the third portion PA3 and the fourth portion PA4 may be 1 μm or less. Accordingly, the embodiments may minimize or reduce pressure applied to the fourth portion PA2 by a second conductive ball CB2, and thus, may prevent or reduce instances of the fourth portion PA4 breaking.

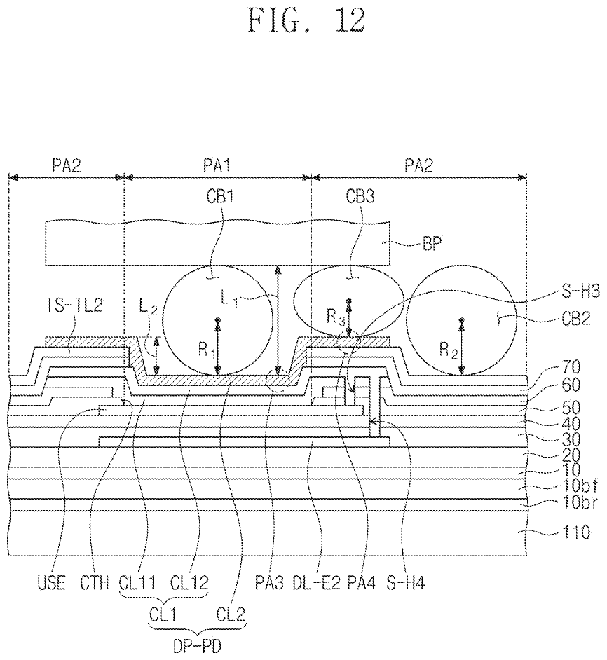

FIG. 12 is a view of an enlarged portion of a display device according to some embodiments of the inventive concept. The display device illustrated in FIG. 12 is different from the display device described with reference to FIG. 1 to FIG. 9 in that an end portion and a shielding electrode are located on the same layer, and that an upper auxiliary electrode is further included.

Referring to FIG. 12, according to some embodiments, an end portion DL-E2 may be located on a second insulation layer 20 (hereinafter, a lower insulation layer). The end portion DL-E2 and the shielding electrode BMLb (see FIG. 4) may be located on the same layer. According to some embodiments, third to fourth insulation layers 30 to 40 (hereinafter, intermediate insulation layers) may be located on the end portion DL-E2. The intermediate insulation layers 30 and 40 may include a first intermediate insulation layer 30 which covers the end portion DL-E2, and a second intermediate insulation layer 40 located between the first intermediate insulation layer 30 and an upper auxiliary electrode USE. A fifth insulation layer 50 (hereinafter, an upper insulation layer) may be located on the intermediate insulation layers 30 to 40. On the upper insulation layer 50, a contact hole CTH may be defined.

The embodiments may include the upper auxiliary electrode USE located on the second intermediate insulation layer 40. The upper auxiliary electrode USE may include a first portion PA1 exposed by the contact hole CTH and a second portion PA2 covered by the upper insulation layer 50. An uppermost conductive pattern CL2 may be electrically connected to the upper auxiliary electrode USE.

According to some embodiments, the upper insulation layer 50 may have a first sub-contact hole S-H3 overlapping the second portion PA2. The upper insulation layer 50 and the intermediate insulation layers 20 to 40 may have a second sub-contact hole S-H4 overlapping the second portion PA.

Meanwhile, the embodiments may further include an intermediate conductive pattern CL1 located between the uppermost conductive pattern CL2 and the upper auxiliary electrode USE. The uppermost conductive pattern CL2 may be electrically connected to the upper auxiliary electrode USE through the intermediate conductive pattern CL1.

The intermediate conductive pattern CL1 may be connected to the upper auxiliary electrode USE through the first sub-contact hole S-H3. The intermediate conductive pattern CL1 may be connected to the end portion DL-E2 through the second sub-contact S-H4.

Meanwhile, the intermediate conductive pattern CL1 may include a first intermediate conductive pattern CL11 and a second intermediate conductive pattern CL12 located on the first intermediate conductive pattern CL11. The first intermediate conductive pattern CL11 may be connected to the upper auxiliary electrode USE through the first sub-contact hole S-H3. The first intermediate conductive pattern CL11 may be connected to the end portion DL-E2 through the second sub-contact S-H4.

The display device according to some embodiments includes the upper auxiliary electrode USE, and thus, may reduce a separation distance L1 between a third portion PA3 and a bump BP in a third direction DR3. For example, the separation distance L1 between the third portion PA3 and the bump BP in the third direction DR3 may be 3 μm or less. In addition, some embodiments include the upper auxiliary electrode USE, and thus, may reduce a height difference L2 between a third portion PA3 and a fourth portion PA4. For example, the height difference L2 between the third portion PA3 and the fourth portion PA4 may be 1 μm or less. Accordingly, some embodiments may minimize or reduce pressure applied to the fourth portion PA2 by a second conductive ball CB2, and thus, may prevent or reduce breakage of the fourth portion PA4.

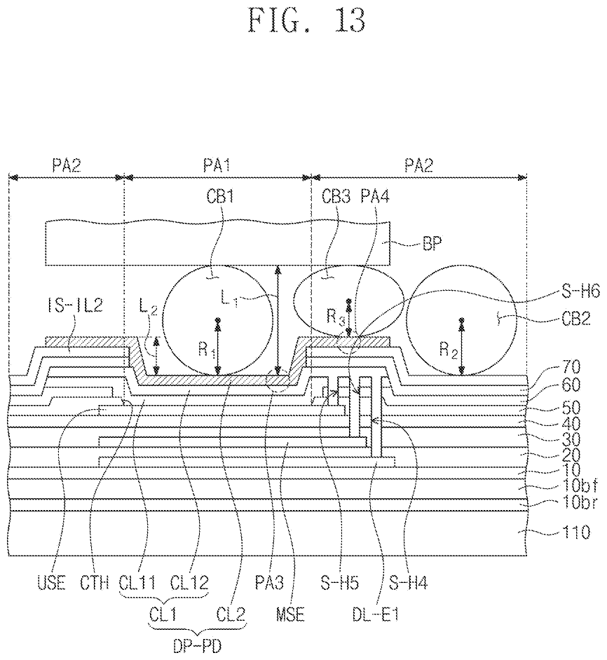

FIG. 13 is a view of an enlarged portion of a display device according to some embodiments of the inventive concept. The display device illustrated in FIG. 13 is different from the display device described with reference to FIG. 1 to FIG. 9 in that an end portion and a first gate are located on the same layer, and that an upper auxiliary electrode and a lower auxiliary electrode are further included.

Referring to FIG. 13, according to some embodiments, an end portion DL-E1 may be located on a first insulation layer 10 (hereinafter, a lower insulation layer). The end portion DL-E1 and the first gate GT1 (see FIG. 4) may be located on the same layer.

According to some embodiments, the second to fourth insulation layers 20 to 40 (hereinafter, intermediate insulation layers) may be located on the end portion DL-E1. A fifth insulation layer 50 (hereinafter, an upper insulation layer) may be located on the intermediate insulation layers 20 to 40. On the upper insulation layer 50, a contact hole CTH may be defined.

The embodiments may include an upper auxiliary electrode USE located on the intermediate insulation layers 20 to 40. The upper auxiliary electrode USE may include a first portion PA1 exposed by the contact hole CTH and a second portion PA2 covered by the upper insulation layer 50. An uppermost conductive pattern CL2 may be electrically connected to the upper auxiliary electrode USE.

The intermediate insulation layers 20 to 40 may include a first intermediate insulation layer 20 which covers the end portion DL-E1, a second intermediate insulation layer 30 located between the first intermediate insulation layer 20 and the upper insulation layer 50, and a third intermediate insulation layer 40 located between the second intermediate insulation layer 30 and the upper insulation layer 50. The first intermediate insulation layer 20 may cover the end portion DL-E1.

A lower auxiliary electrode MSE may be located on the first intermediate insulation layer 20. The second intermediate insulation layer 30 may cover the lower auxiliary electrode MSE. The upper auxiliary electrode USE may be located on the third insulation layer 40.

Meanwhile, some embodiments may further include an intermediate conductive pattern CL1 located between the uppermost conductive pattern CL2 and the upper auxiliary electrode USE. The uppermost conductive pattern CL2 may be electrically connected to the upper auxiliary electrode USE through the intermediate conductive pattern CL1.

The intermediate conductive pattern CL1 may be connected to the upper auxiliary electrode USE through the first sub-contact hole S-H3. The intermediate conductive pattern CL1 may be connected to the end portion DL-E1 through the second sub-contact S-H4.

According to some embodiments, the upper insulation layer 50 may have a first sub-contact hole S-H5 overlapping the second portion PA2. The upper insulation layer 50, the second intermediate insulation layer 30, and the third intermediate insulation layer 40 may have a second sub-contact hole S-H6 in the second portion PA2. The upper insulation layer 50, the first intermediate insulation layer 20, the second intermediate insulation layer 30, and the third intermediate insulation layer 40 may have a third sub-contact hole S-H7 in the second portion PA2.

Meanwhile, the intermediate conductive pattern CL1 may include a first intermediate conductive pattern CL11 and a second intermediate conductive pattern CL12 located on the first intermediate conductive pattern CL11. The first intermediate conductive pattern CL11 may be connected to the upper auxiliary electrode USE through the first sub-contact hole S-H5. The first intermediate conductive pattern CL11 may be connected to the lower auxiliary electrode MSE through the second sub-contact hole S-H6. The first intermediate conductive pattern CL11 may be connected to the end portion DL-E1 through the third sub-contact S-H7.

The display device according to some embodiments includes the upper auxiliary electrode USE and the lower auxiliary electrode MSE, and thus, may reduce a separation distance L1 between a third portion PA3 and a bump BP in a third direction DR3. For example, the separation distance L1 between the third portion PA3 and the bump BP in the third direction DR3 may be 3 μm or less. In addition, the embodiments include the upper auxiliary electrode USE, and thus, may reduce a height difference L2 between a third portion PA3 and a fourth portion PA4. For example, the height difference L2 between the third portion PA3 and the fourth portion PA4 may be 1 μm or less. Accordingly, the embodiments may minimize or reduce pressure applied to the fourth portion PA2 by a second conductive ball CB2, and thus, may prevent or reduce the breakage of the fourth portion PA4.

A display device according to some embodiments adjusts a separation distance between a first portion of an uppermost conductive pattern and a connection terminal in a thickness direction, and thus, may minimize pressure applied to a second portion by a conductive ball, and accordingly, may prevent or reduce the breakage of the uppermost conductive pattern.

A display device according to some embodiments includes an end portion located on the same layer as the layer on which a second gate is located, and thus, may minimize or reduce a separation distance between a connection terminal and a first portion of an uppermost conductive pattern. Accordingly, pressure applied to a second portion of the uppermost conductive pattern by a conductive ball may be reduced to prevent or reduce the breakage of the second portion of the uppermost conductive pattern.

A display device according to some embodiments includes an end portion located on the same layer as the layer on which a first gate is located, and includes an upper auxiliary electrode or a lower auxiliary electrode located on the same layer as the layer on which a second gate or a shielding electrode is located, and thus, may minimize a separation distance between a connection terminal and a first portion of an uppermost conductive pattern. Accordingly, pressure applied to a second portion of the uppermost conductive pattern by a conductive ball may be reduced to prevent or reduce the breakage of the second portion of the uppermost conductive pattern.

Although the present invention has been described with reference to some embodiments of the present invention, it will be understood by those skilled in the art that various modifications and changes in form and details may be made therein without departing from the spirit and scope of the present invention as set forth in the following claims. Accordingly, the technical scope of the present invention is not intended to be limited to the contents set forth in the detailed description of the specification, but is intended to be defined by the appended claims, and their equivalents.

What is claimed is:

1. A display device comprising:
a display panel including a display region and a non-display region adjacent to the display region;
an electronic component electrically connected to the display panel; and
a conductive adhesive layer including an adhesive layer and a plurality of conductive balls in the adhesive layer and defining a single layer, and electrically connecting the display panel and the electronic component,
wherein the display panel includes:
a base layer;
a pixel on the base layer, and including a pixel driving circuit which includes a silicon transistor having a first gate, an oxide transistor having a second gate above the silicon transistor, and a shielding electrode between the first gate and the second gate and overlapping the oxide transistor, and a light emission element which is electrically connected to the pixel driving circuit;
a signal line overlapping the non-display region, including an end portion on a same layer as the second gate, and electrically connected to the pixel driving circuit;
a signal pad electrically connected to the end portion;
a lower insulation layer on the base layer, and covering the silicon transistor; and
an upper insulation layer on the lower insulation layer, covering the second gate, and having a contact hole defined thereon,
wherein:
the end portion is on the lower insulation layer, and includes a first portion exposed by the contact hole and a second portion covered by the upper insulation layer; and
the signal pad includes an uppermost conductive pattern on the end portion, and electrically connected to the end portion of the signal line, wherein the electronic component includes a connection terminal on the uppermost conductive pattern, and electrically connected to the uppermost conductive pattern through the conductive adhesive layer.

2. The display device of claim 1, wherein the conductive balls comprise a first conductive ball overlapping the first portion and the connection terminal, a second conductive ball overlapping the second portion and the connection terminal, and a third conductive ball not overlapping the connection terminal, wherein a separation distance between a portion overlapping the first portion of the uppermost conductive pattern and the connection terminal is the same as or less than a diameter of the third conductive ball in a thickness direction of the display panel and the electronic component.

3. The display device of claim 1, wherein a separation distance between a portion overlapping the first portion of the uppermost conductive pattern and the connection terminal is 3 μm or less in a thickness direction of the display panel and the electronic component.

4. The display device of claim 1, wherein the electronic component is a driving chip, and the connection terminal is a bump.

5. The display device of claim 1, wherein the uppermost conductive pattern comprises a third portion corresponding to the first portion and a fourth portion corresponding to the second portion, wherein a height difference between the third portion and the fourth portion in a thickness direction of the display panel is 1 μm or less.

6. The display device of claim 1, wherein the signal pad further comprises an intermediate conductive pattern between the uppermost conductive pattern and the end portion, and electrically connecting the uppermost conductive pattern and the end portion.

7. The display device of claim 6, wherein the intermediate conductive pattern comprises:
a first intermediate conductive pattern adjacent to the end portion; and
a second intermediate conductive pattern between the first intermediate conductive pattern and the uppermost conductive pattern.

8. The display device of claim 7, wherein the upper insulation layer has a sub-contact hole in a portion overlapping the second portion, wherein the second intermediate conductive pattern is connected to the end portion through the sub-contact hole.

9. The display device of claim 7, further comprising:
a first organic layer on the upper insulation layer;
a second organic layer on the first organic layer;
a first connection electrode between the upper insulation layer and the first organic layer, and electrically connected to the silicon transistor or the oxide transistor; and
a second connection electrode between the first organic layer and the second organic layer, and connecting the first connection electrode and the light emission element.

10. The display device of claim 9, wherein:
the first intermediate conductive pattern and the first connection electrode comprise a same material; and
the second intermediate conductive pattern and the second connection electrode comprise a same material.

11. The display device of claim 1, further comprising an input sensor including at least one insulation layer and at least one conductive pattern layer, and on the display panel, wherein the uppermost conductive pattern and the at least one conductive pattern layer include a same material.

12. A display device comprising:
a display panel including a display region and a non-display region adjacent to the display region;
an electronic component electrically connected to the display panel; and
a conductive adhesive layer including an adhesive layer and a plurality of conductive balls in the adhesive layer and defining a single layer, and electrically connecting the display panel and the electronic component,
wherein the display panel includes:
a base layer;
a pixel on the base layer, and including a pixel driving circuit which includes a silicon transistor having a first gate, an oxide transistor having a second gate above the silicon transistor, and a shielding electrode between the first gate and the second gate and overlapping the oxide transistor, and a light emission element which is electrically connected to the pixel driving circuit;
a signal line overlapping the non-display region, including an end portion on a same layer as the first gate or the shielding electrode, and electrically connected to the pixel driving circuit;
a signal pad electrically connected to the end portion;
an intermediate insulation layer overlapping the pixel, and between the end portion and the signal pad;
an upper insulation layer on the intermediate insulation layer, and having a contact hole defined thereon; and
an upper auxiliary electrode on the intermediate insulation layer, and a first portion exposed by the contact hole and a second portion covered by the upper insulation layer, wherein the signal pad includes an uppermost conductive pattern is on the upper auxiliary electrode, and electrically connected to the upper auxiliary electrode, and the electronic component includes a connection terminal is on the uppermost conductive pattern, and electrically connected to the uppermost conductive pattern through the conductive adhesive layer.

13. The display device of claim 12, wherein the conductive balls comprise a first conductive ball overlapping the first portion and the connection terminal, a second conductive ball overlapping the second portion and the connection terminal, and a third conductive ball not overlapping the connection terminal, wherein a separation distance between a portion overlapping the first portion of the uppermost conductive pattern in a thickness direction of the display panel and the electronic component and the connection terminal is the same as or less than a diameter of the third conductive ball in the thickness direction.

14. The display device of claim 13, wherein a diameter of the first conductive ball in the thickness direction is the same as or less than the diameter of the third conductive ball in the thickness direction.

15. The display device of claim 12, wherein a separation distance between the uppermost conductive pattern and the connection terminal is 3 μm or less in a thickness direction of the display panel and the electronic component.

16. The display device of claim 12, wherein the uppermost conductive pattern comprises a third portion corresponding to the first portion and a fourth portion corresponding to the second portion, wherein a height difference between the third portion and the fourth portion in a thickness direction of the display panel is 1 μm or less.

17. The display device of claim 12, wherein the signal pad further comprises an intermediate conductive pattern between the upper auxiliary electrode and the uppermost conductive pattern, and electrically connecting the uppermost conductive pattern and the upper auxiliary electrode.

18. The display device of claim 17, wherein:
the upper insulation layer has a first sub-contact hole overlapping the second portion; and
the upper insulation layer and the intermediate insulation layer have a second sub-contact hole overlapping the second portion,
wherein:
the intermediate conductive pattern is connected to the upper auxiliary electrode through the first sub-contact hole; and
the intermediate conductive pattern is connected to the end portion through the second sub-contact hole.

19. The display device of claim 12, further comprising a lower auxiliary electrode between the end portion and the upper auxiliary electrode, and electrically connected to each of the end portion and the upper auxiliary electrode, wherein the intermediate insulation layer includes a first intermediate insulation layer which covers the end portion and a second intermediate insulation layer which covers the lower auxiliary electrode.

20. The display device of claim 19, wherein the signal pad further comprises an intermediate conductive pattern between the upper auxiliary electrode and the uppermost conductive pattern, and electrically connecting each of the uppermost conductive pattern, the upper auxiliary electrode, and the lower auxiliary electrode, wherein:
the upper insulation layer has a first sub-contact hole overlapping the second portion;
the upper insulation layer and the second intermediate insulation layer have a second sub-contact hole overlapping the second portion; and
the upper insulation layer, the first intermediate insulation layer, and the second intermediate insulation layer have a third sub-contact hole overlapping the second portion, wherein:
the intermediate conductive pattern is connected to the upper auxiliary electrode through the first sub-contact hole;
the intermediate conductive pattern is connected to the lower auxiliary electrode through the second sub-contact hole; and
the intermediate conductive pattern is connected to the end portion through the third sub-contact hole.
